(19) United States
(12) Patent Application Publication
(10) Pub. No.: US 2023/0033569 A1
(43) Pub. Date: Feb. 2, 2023

(54) LOW POWER FINITE IMPULSE RESPONSE FILTER

(71) Applicant: STMicroelectronics International N.V., Geneva (CH)

(72) Inventors: Ankur BAL, Greater Noida (IN); Rupesh SINGH, Ghaziabad (IN)

(73) Assignee: STMicroelectronics International N.V., Geneva (CH)

(21) Appl. No.: 17/867,496

(22) Filed: Jul. 18, 2022

Related U.S. Application Data
(60) Provisional application No. 63/227,129, filed on Jul. 29, 2021.

(51) Int. Cl. H03H 17/02

(52) U.S. Cl. CPC H03H 17/0223; H03H 2017/0081

(57) ABSTRACT

A finite impulse response (FIR) filter includes a plurality of registers. The data input terminal of each register is directly coupled to the input of the FIR filter. A new data value is passed to each register on each clock cycle of a filter clock signal. Only one of the registers processes the data value on each clock cycle. A ring counter is coupled to the registers and determines which register processes the data value on each dock cycle.

### BACKGROUND

### Technical Field

The present disclosure generally relates to digital filters. The present disclosure relates more particularly to finite impulse response filters.

### Description of the Related Art

Many integrated circuits include signal processing circuitry. The signal processing circuitry may include various processing blocks for processing analog signals and digital signals. Various filter blocks may be utilized for filtering analog and digital signals.

There are many types of digital filters that can be utilized to filter digital signals as part of a digital signal processor. One example of a digital filter is a finite impulse response (FIR) filter. Full throughput FIR filters are often major components of signal processing chains. FIR filters may consume large amounts of power. In some cases, FIR filters may be responsible for more than 50% of the total power consumption of a digital signal processing filter chain. This is due, in part, to the fact that many FIR filters utilize power intensive convolution operations.

While it may be desirable to reduce the power consumption of a FIR filter, such reductions in power consumption typically come at the cost of performance. It has proven very difficult to implement a low-power FIR filter with high performance.

### BRIEF SUMMARY

Embodiments of the present disclosure provide a FIR filter that consumes low amounts of power while providing very high performance. The FIR filter receives a new data value with each cycle of a filter clock. Each of a plurality of input registers simultaneously receives each data value. However, only one input register processes a data value on each clock cycle. This arrangement, coupled with a compatible arrangement of downstream circuitry, provides a very high performance and low power FIR filter.

The FIR filter may include a ring counter having a plurality of flip-flops coupled in a ring configuration. The output of each flip-flop is provided to both the data input of the next flip-flop and to the clock input terminal of a respective input register. A single pulse is passed through the ring counter such that on each clock cycle the output of only one of the flip-flops is high. The input register coupled to the flip-flop with the high output on any given clock cycle processes the data value. This not only provides the aforementioned benefits of ensuring that only one input register processes a data value on each clock cycle, but also greatly simplifies and reduces the power consumption associated with distributing clock signals to the input registers.

The FIR filter may include a plurality of convolution operators each coupled to a respective input register. The FIR filter may include a plurality of multiplexers coupled to the convolution operators. Each multiplexer provides a different convolution constant to the corresponding convolution operator on each clock cycle. The FIR filter includes a summer that sums the outputs of all the convolution operators.

As will be set forth in more detail below, various configurations of FIR filters can be implemented in accordance with principles of the present disclosure.

### BRIEF DESCRIPTION OF THE SEVERAL VIEWS OF THE DRAWINGS

FIG. 1 is a block diagram of a FIR filter, according to some embodiments.

FIG. 2 is a schematic diagram of a FIR filter, according to some embodiments.

FIG. 3 illustrates signals associated with a FIR filter, according to some embodiments.

FIG. 4 is a schematic diagram of the convolution operator of a FIR filter, according to some embodiments.

FIG. 5 is a flow diagram of a method for operating a FIR filter, according to some embodiments.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known structures, circuits, and processes associated with finite impulse response filters have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

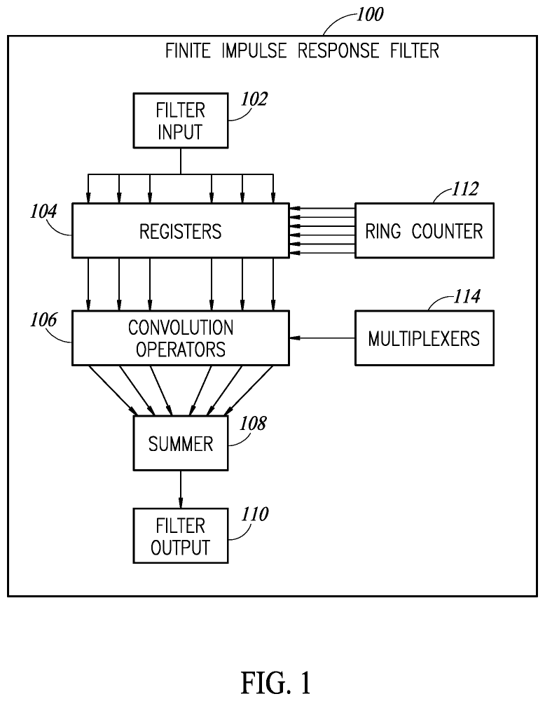

FIG. 1 is a block diagram of a FIR filter 100, according to some embodiments. As will be set forth in more detail below, the FIR filter 100 utilizes parallel input data distribution and single pulse clock distribution in order to consume relatively small amounts of power while providing very high performance. Various arrangements of circuit components can be utilized in accordance with principles of the present disclosure without departing from the scope of the present disclosure.

The FIR filter 100 includes a filter input 102. The filter input 102 receives a series of data values. The FIR filter 100 is governed by a filter clock signal. The filter input 102 receives a new data value on each cycle of the clock signal. The data values may be multibit data values. For example, each data value may be an eight bit data value, a 12 bit data value, a 16 bit data value, etc.

The FIR filter 100 includes a plurality of registers 104. Each register 104 has a data input, a data output, and a clock input. Each register 104 acts as a temporary memory for storing data values received from the filter input 102. Each register is configured to receive, on its data input terminal, a data value and to output the data value on its data output terminal.

The data input terminal of each register 104 is coupled to the filter input 102. The data input terminals of the registers 104 are in parallel to each other. The data value from the filter input 102 is provided substantially simultaneously to the data input terminals of each of the registers 104. The benefits of this configuration will be made more apparent further below.

Each register 104 may include a plurality of flip-flops. If the data values are 16-bit data values, then the registers may each include 16 flip-flops. Each of the flip-flops receives a particular bit of the data values and outputs that bit on its data output terminal. The data output terminal of a register includes a plurality of individual bit outputs that collectively make up the data output terminal. Accordingly, the data output terminal of the register 104 includes the data output terminals of the plurality of flip-flops that make up the register 104.

A traditional design of a FIR filter includes a plurality of registers coupled together in a shift register configuration. In the shift register configuration, the data input terminal of a first register receives the input data value directly from the filter input. After the first register, the data input terminal of each register of the chain of registers is directly coupled to the data output terminal of the immediately preceding register of the chain of registers. On a first clock cycle, the first register receives the first data value. On a second clock cycle, the first register receives a second data value in the first and values passed to the second register from the first register. On the third clock cycle, the first register receives a third data value, the second data values passed to the second register, and the first data value is passed to the third register. Accordingly, on each clock cycle each register processes a data value. In the example in which each register includes 16 flip-flops, all 16 flip-flops of all registers process a data value on every clock cycle. This results in an enormous expenditure of power.

Furthermore, in the traditional design of a FIR filter, in order to ensure that the clock terminals of all of the flip-flops of all the registers meet their timing windows, complex clock trees are designed in order to ensure that the rising edge of clock signal arrives at each of the clock terminals of each of the flip-flops of each of the registers substantially simultaneously. This consumes a large amount of circuit area and expends a large amount of power.

Returning to FIG. 1, the FIR filter 100 includes a ring counter 112. The ring counter 112 acts as a sort of clock signal for the registers 104. The ring counter 112 includes a plurality of outputs. Each output of the ring counter 112 is coupled to the clock input terminal of a respective register 104. The ring counter 112 receives the filter clock signal, but does not provide the filter clock signal to the registers 104. Instead, only one of the outputs of the ring counter is high on each cycle of the filter clock signal. The ring counter 112 operates as though a single pulse is passed around the ring. On a first cycle of the filter clock, the pulse is at the first output of the ring counter 112 while all other outputs of the ring counter 112 are low. On a second cycle of the filter clock, the pulse is at the second output of the ring counter 112 while all other outputs of the ring counter 112 are low, and so forth as the pulse travels through all of the outputs of the ring counter 112.

If there are n registers 104 and n outputs of the ring counter 112, each output of the ring counter 112 goes high once in every n cycles of the filter clock. On a first cycle of the filter clock, a first data value is received at each of the data input terminals of the registers 104. The pulse is at the first output of the ring counter 112 while all other outputs of the ring counter 112 are low. This means that the clock input terminal of only the first register 104 goes high. Accordingly, only the first register 104 passes the first data value to its data output terminal. On a second cycle of the filter clock, a second data value is received at each of the data input terminals of the registers 104. The pulse is now at the second output of the ring counter 112 while all other outputs of the ring counter 112 are low. This means that the clock input terminal of only the second register 104 goes high. Accordingly, only the second register 104 passes the second data value to its data output terminal. This continues and eventually all n registers 104 hold a respective data value. The pulse eventually returns to the first output of the ring counter 112 and an n+1th data value is received and passed to the data output terminal of the first register, replacing the first data value. In this way, each register 104 processes a data value once in every n clock cycles. Each data value is processed by only one register 104.

In some embodiments, the ring counter 112 includes a plurality of flip-flops coupled in a circular chain. The data input terminal of each flip-flop is coupled to the data output terminal of the next flip-flop in the chain. The data input terminal of a first flip-flop is coupled to the data output terminal of the last flip-flop. The data output terminal of each flip-flop corresponds to a respective output of the ring counter 112. Accordingly, the data output terminal of each flip-flop is coupled to a respective register 104. The clock terminal of each flip-flop receives the filter clock signal. A first flip-flop in the chain of flip-flops has a reset condition that results in the output of the first flip-flop going high upon a reset. Such a reset initiates the pulse. None of the other flip-flops of the chain of flip-flops of the ring counter 112 has such a reset condition.

When the first flip-flop receives the reset signal, the data output of the first flip-flop goes high. This corresponds to the first output of the ring counter 112 going high. The clock input terminal of the first register 104 also goes high and the first register 104 processes a data value, as described previously. Because the output of the first flip-flop goes high during the first clock cycle, the input of the second flip-flop is high during the first clock cycle. At the rising edge of the second clock cycle, the high-value is passed from the input of the second flip-flop to the output of the second flip-flop. On the rising edge of the third clock cycle, the high-value is passed from the input of the third flip-flop to the output of the third flip-flop. This goes around the ring of flip-flops indefinitely. The output of each flip-flop goes high once in every n clock cycles. Other configurations of a ring counter 112 can be utilized without departing from the scope of the present disclosure. Furthermore, other circuits that cause the clock input terminal of only one of the registers 104 to go high on each clock cycle can be utilized without departing from the scope of the present disclosure.

The FIR filter 100 includes convolution operators 106. There is a respective convolution operator 106 for each register 104. Each convolution operator 106 includes a data input terminal, a data output terminal, and one or more convolution coefficient input terminals. The data input terminal of each convolution operator 106 is coupled to the data output terminal of a respective register 104.

When a first convolution operator receives the first data value from the first register 104, the first convolution operator 106 performs the convolution operation on the first data value. The first convolution operator 106 performs the convolution operation on the first data value by convolving the first data value with one or more convolution coefficients. The first convolution operator 106 outputs a convolved data value on its data output terminal. Each of the convolution operators 106 performs the convolution operation on the data value at the data output terminal of the respective register 104.

The convolution operation may include adding an addition parameter to the data value. The convolution operation may then include multiplying the sum by a convolution or multiplication parameter.

In a traditional FIR filter, each convolution operator has one or more fixed convolution coefficients. Because each data value passes through each register of the traditional FIR filter, each data value eventually passes through each convolution operator and is convolved with the individual convolution coefficient of each convolution operator.

However, in the FIR filter 100, each data value passes through only one of the registers 104 and, thus, is passed through only one of the convolution operators 106. In order to ensure that each data value is convolved with each of a plurality of convolution operators, the convolution operators 106 of the FIR filter 100 does not receive static convolution coefficients. Instead, the convolution coefficients for each convolution operator 106 change on each clock cycle. In the example in which there are n registers 104 and n convolution operators 106, there may also be n different convolution coefficient values. Because the first data value remains at the output of the first register 104 for n clock cycles, if the first convolution operator 106 receives a different convolution coefficient on each clock cycle, then the first convolution operator 106 will convolve the first data value with each of the n convolution coefficients.

The FIR filter 100 includes a plurality of multiplexers 114 in order to ensure that each data value is convolved with each convolution coefficient. Each multiplexer 114 has n inputs, one output, and a control terminal. Each multiplexer 114 receives, on its inputs, the different convolution coefficients. The output of each multiplexer 114 is coupled to the convolution coefficient input terminal of a respective convolution operator 106. The control terminal of each multiplexer 114 receives a signal that causes the output of the multiplexer 114 to switch to a next input on each clock cycle such that each input is passed to the output once in every n clock cycles. In this way, each convolution operator 106 receives each of the convolution coefficients every n clock cycles. In some cases, there may be fewer convolution coefficients than n, for example n/2 convolution coefficients. The multiplexers 114 can be appropriately operated to ensure that each convolution coefficient is passed to each convolution operator at least once in every n clock cycles. Other configurations of convolution operators 106a and multiplexers 114 can be utilized without departing from the scope of the present disclosure.

The FIR filter 100 includes a summer 108. The summer 108 includes n input terminals and one output terminal. Each input terminal is coupled to the data output terminal of a respective convolution operator 106. Accordingly, the summer 108 receives all of the convolved data values from the convolution operators 106. The summer 108 adds the convolved the data values together and provides the sum data value 108 on the data output terminal of the summer 108. While a single summer 108 is shown in FIG. 1, in practice, there can be multiple summers 108 that collectively operate to sum the outputs of all of the convolution operators 106.

The FIR filter 100 includes a filter output 110. The filter output 110 receives the sum data value from the summer 108 and outputs the sum data value as the final output of the FIR filter 100.

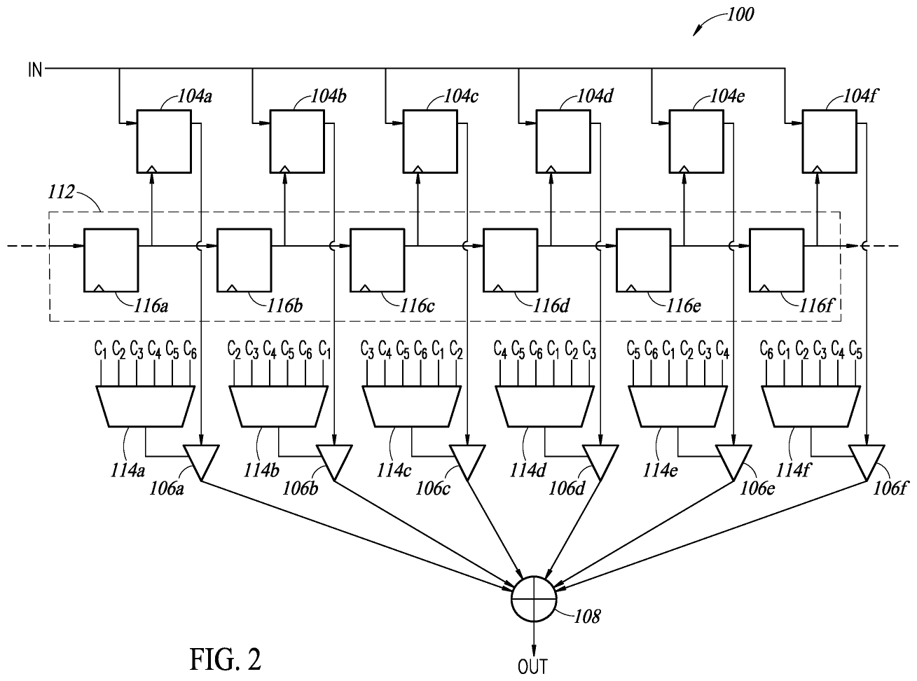

FIG. 2 is a schematic diagram of a FIR filter 100, according to some embodiments. The FIR filter 100 includes a data input terminal IN. The data input terminal IN receives a series of data values. A new data value is received on each cycle of a filter clock received by the FIR filter 100.

The filter clock may be a high frequency filter clock. The frequency of the filter clock may be between 1 GHz and 5 GHz. Accordingly, the FIR filter 100 is capable of high frequency operation while maintaining relatively low power consumption. The filter clock can have other frequency ranges without departing from the scope of the present disclosure.

The FIR filter 100 includes six registers 104a-f. While FIG. 2 illustrates an example in which there are six registers 104a-f, the circuit of FIG. 2 may be generalized to n registers. Accordingly, in the example of FIG. 2, n=6, though other values of n may be utilized without departing from the scope of the present disclosure.

The data input terminal of each register 104a-f is coupled to the filter input IN. Accordingly, each register 104a-f receives each data value substantially simultaneously at its data input terminal.

The FIR filter 100 includes a ring counter 112. The ring counter 112 includes six flip-flops 116a-f. Each flip-flop 116a-f includes a data input terminal, a data output terminal, and a clock input terminal. The flip-flops 116a-f are coupled in a ring configuration. The data output terminal of the flip-flop 116a is coupled to the data input terminal of the flip-flop 116b. The data output terminal of the flip-flop 116b is coupled to the data input terminal of the flip-flop 116c. The data output terminal of the flip-flop 116c is coupled to the data input terminal of the flip-flop 116d. The data output terminal of the flip-flop 116d is coupled to the data input terminal of the flip-flop 116e. The data output terminal of the flip-flop 116e is coupled to the data input terminal of the flip-flop 116f. The data output terminal of the flip-flop 116f is coupled to the data input terminal of the flip-flop 116a.

In one example, the flip-flop 116a has a different set/reset condition than the other flip-flops 116b-f. Upon receiving a reset signal at the set reset terminal (not shown), the output of the flip-flop 116a goes high at the rising edge of the first clock cycle even though the data input terminal was initially low. This corresponds to the initiation of a pulse that will make a complete circuit around the ring oscillator 112 every six clock cycles. The set/reset terminals of the flip-flops 116a-f are not shown in FIG. 2. Though not shown in FIG. 2, the clock input terminals of the flip-flops 116a-f all receive the filter clock signal.

At the rising edge of the second clock cycle, the data output terminal of the flip-flop 116b goes high because the data input terminal of the flip-flop 116a was high at the rising edge of the second clock cycle. The data output terminal of the flip-flop 116a goes low at the rising edge of the second clock cycle. The data output terminals of all the other flip-flops are low. The rising edge of the third clock cycle the data output terminal of the flip-flop 116c goes high. At the rising edge of the fourth clock cycle, the data output terminal of the flip-flop 116d goes high. At the rising edge of the fifth clock cycle, the data output terminal of the flip-flop 116e goes high. At the rising edge of the sixth clock cycle the data output terminal of the flip-flop 116f goes high. At the rising edge of the seventh clock cycle, the data output terminal of the flip-flop 116a goes high again and the cycle repeats indefinitely as the pulse travels around the ring counter 112.

The data output terminal of the flip-flop 116a is coupled to the clock input terminal of the register 104a. The data output terminal of the flip-flop 116b is coupled to the clock input terminal of the register 104b. The data output terminal of the flip-flop 116c is coupled to the clock input terminal of the register 104c. The data output terminal of the flip-flop 116d is coupled to the clock input terminal of the register 104d. The data output terminal of the flip-flop 116e is coupled to the clock input terminal of the register 104e. The data output terminal of the flip-flop 116f is coupled to the clock input terminal of the register 104f.

On the first clock cycle, a first data value is received at IN. On the first clock cycle, the clock input terminal of the register 104a goes high. The first data value is passed from the data input terminal of the register 104a to the data output terminal of the register 104a. On the second clock cycle, the clock input terminal of the register 104b goes high and IN receives a second data value. The second data value is passed from the filter input IN to the data output terminal of the second register 104b. On the third clock cycle, the clock input terminal of the register 104c goes high and IN receives a third data value. The third data value is passed from the filter input IN to the data output terminal of the third register 104c. On the fourth clock cycle, the clock input terminal of the register 104d goes high and a fourth data value is received at IN. The fourth data value is passed from the filter input IN to the data output terminal of the register 104d. On the fifth clock cycle, the clock input terminal of the register 104e goes high and IN receives a firth data value. The fifth data value is passed from the filter input IN to the data output terminal of the register 104d. On the sixth clock cycle, the clock input terminal of the register 104f goes high and IN receives a sixth data value. The sixth data value is passed from the filter input IN to the data output terminal of the register 104f. On the seventh clock cycle, the clock input terminal of the register 104a goes high and IN receives a seventh data value. The seventh data value is passed to the data output terminal of the register 104a. This continues in a cycle as each register 104a-f processes a data value once in every six clock cycles. The data output terminal of each register 104a-f holds the data value for six clock cycles.

The FIR filter 100 includes six convolution operators 106a-f. Each convolution operator 106a-f includes a data input terminal, a data output terminal, and a convolution coefficient input terminal. The data input terminal of the convolution operator 106a is coupled to the data output terminal of the register 104a. The data input terminal of the convolution operator 106b is coupled to the data output terminal of the register 104b. The data input terminal of the convolution operator 106c is coupled to the data output terminal of the register 104c. The data input terminal of the convolution operator 106d is coupled to the data output terminal of the register 104d. The data input terminal of the convolution operator 106e is coupled to the data output terminal of the register 104e. The data input terminal of the convolution operator 106f is coupled to the data output terminal of the register 104f.

The FIR filter 100 includes six multiplexers 114a-f. Each multiplexer 114a-f includes six input terminals and one output terminal. The six input terminals of each multiplexer 114a-f each receive one of six convolution coefficients C1-C6. Each multiplexer 114a-f receives the six convolution coefficients C1-C6 in a different order. The output of the multiplexer 114a is coupled to the convolution coefficient input terminal of the convolution operator 106a. The output of the multiplexer 114b is coupled to the convolution coefficient input terminal of the convolution operator 114b. The output of the multiplexer 114c is coupled to the convolution coefficient input terminal of the convolution operator 114c. The output of the multiplexer 114d is coupled to the convolution coefficient input terminal of the convolution operator 114d. The output of the multiplexer 114e is coupled to the convolution coefficient input terminal of the convolution operator 114e. The output of the multiplexer 114f is coupled to the convolution coefficient input terminal of the convolution operator 114f.

On each clock cycle, the multiplexers 114a-f couple a different input to the output such that every six clock cycles, each of the convolution coefficients C1-C6 are provided to each of the convolution operators 106a-f, though in different orders. For example, on a first clock cycle, the multiplexer 114a outputs the convolution coefficient C1, while the multiplexer 114b outputs the convolution coefficient C2. On a second clock cycle, the multiplexer 114a outputs the convolution coefficient C2. On the third clock cycle, the multiplexer 114a outputs the third convolution coefficient C3. On the fourth clock cycle, the multiplexer 114a outputs the fourth convolution coefficient C4. On the fifth clock cycle, the multiplexer 114a outputs the fifth convolution coefficient C5. On the sixth clock cycle, the multiplexer 114a outputs the sixth convolution coefficient C6. The convolution coefficients C1-C6 may correspond to various scalar values utilized for convolution operations.

The convolution operators 106a-f output convolved data values corresponding to the data values output from the registers 104a-f but convolved with the convolution coefficients C1-C6. The convolved data values change on each clock cycle as the output of the multiplexers 114a-f change.

The FIR filter 100 includes a summer 108. The summer 108 sums the convolved data values on each clock cycle. The output of the summer 108 is the output of the FIR filter 100.

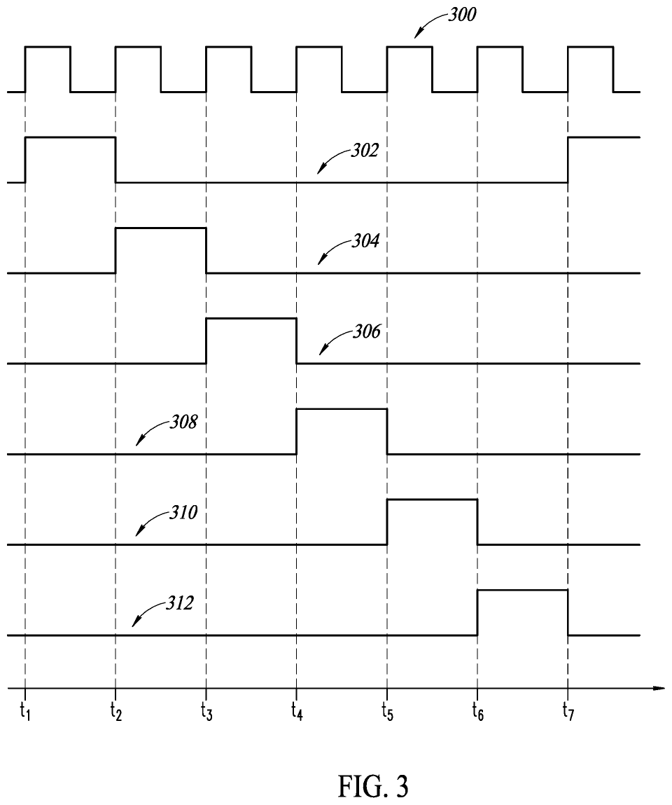

FIG. 3 is a plurality of graphs illustrating signals associated with the FIR filter 100 of FIG. 2, according to some embodiments. The graph 300 corresponds to the filter clock signal. The graph 302 corresponds to the data output terminal of the flip-flop 116a. The graph 304 corresponds to the data output terminal of the flip-flop 116b. The graph 306 corresponds to the data output terminal of the flip-flop 116c. The graph 308 corresponds to the data output terminal of the flip-flop 116d. The graph 310 corresponds to the data output terminal of the flip-flop 116e. The graph 312 corresponds to the data output terminal of the flip-flop 116f. The graphs 302-312 likewise correspond to the clock input terminals of the registers 104a-f.

At time t1 the ring counter pulse is initiated at the rising edge of the first clock cycle. This corresponds to the data output terminal of the flip-flop 116a going high. At the rising edge of the second clock signal at time t2, the data output terminal of the flip-flop 116 a goes low and the data output terminal of the flip-flop 116b goes high. At the rising edge of the third clock cycle at time t3, the data output terminal of the flip-flop 116b goes low in the data output terminal of the flip-flop 116c goes high. At the rising edge of the fourth clock cycle at time t4, the data output terminal of the flip-flop 116c goes low and the data output terminal of the flip-flop 116d goes high. At the rising edge of the fifth clock cycle at time t5, the data output terminal of the flip-flop 116d goes low and the data output terminal of the flip-flop 116e goes high. At the rising edge of the sixth clock cycle at time t6, the data output terminal of the flip-flop 116e goes low and the data output terminal of the flip-flop 116f goes high. At the rising edge of the seventh clock cycle, the data output terminal of the flip-flop 116f goes low and the data output terminal of the flip-flop 116a goes high.

The output signal of each flip-flop of the ring counter 112 may be considered a respective register clock signal. The respective register clock signals have a period of n*fc, where fc is the frequency of the filter clock. The respective register clock signals differ from traditional clock signals in that they are each high for only 1/n of each register clock cycle, rather than for half of each register clock cycle. The signals 302-312 correspond to register clock signals.

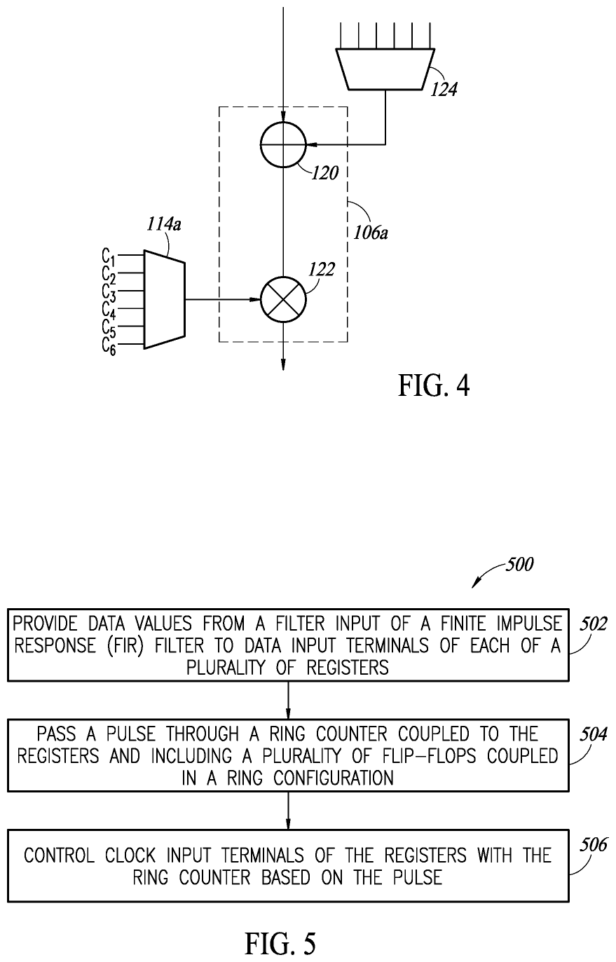

FIG. 4 is a schematic diagram of the convolution operator 106a, in accordance with some embodiments. The convolution operator 106a includes a summer 120 and the multiplier 122. The summer 120 receives the data value from the data output terminal of the register 104a. The summer 120 also receives the output of a multiplexer 124. The multiplexer 124 receives data values from the data output terminals of other registers 104 and outputs them to the summer 120, changing the selected input on each clock cycle. The summer 120 sums the data value from the register 104 a with the data value from the multiplexer 124 and passes the sum to the multiplier 122. The multiplier 122 multiplies the sum from the summer 120 by the convolution coefficient C1-C6 provided by the multiplexer 114a. The output of the multiplier 122 corresponds to the output of the convolution operator 106a. Each of the convolution operators 106a-f can be configured similar to the convolution operator 106a of FIG. 4. There is a respective multiplexer 124 coupled to each convolution operator 106a-f.

FIG. 5 is a flow diagram of a method 500 for operating a FIR filter, in accordance with some embodiments. The method 500 can utilize circuits, systems, components, and processes described in relation to FIGS. 1-4. At 502, the method 500 includes providing data values from a filter input of a finite impulse response filter to data input terminals of each of a plurality of registers. At 504, the method 500 includes passing a pulse through a ring counter coupled to the registers and including a plurality of flip-flops coupled in a ring configuration. At 506, the method 500 includes controlling clock input terminals of the registers with the ring counter based on the pulse.

In some embodiments, a FIR filter includes a filter input and a plurality of registers each having a data input coupled to the filter input, a data output, and a clock input terminal. The FIR filter includes a ring counter coupled to the clock input terminals of the registers.

In some embodiments, a FIR filter includes n registers each including an input, an output, and a clock input. The FIR filter includes a ring counter including n flip-flops coupled in a ring configuration and each coupled to a clock input of a respective register.

In some embodiments, a method includes passing data values from a filter input of a finite impulse response filter to data input terminals of each of a plurality of registers. The method includes passing a pulse through a ring counter coupled to the registers and including a plurality of flip-flops coupled in a ring configuration and controlling clock input terminals of the registers with the ring counter based on the pulse.

Various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A finite impulse response (FIR) filter, comprising:
a filter input;
a plurality of registers each having:
a data input terminal coupled to the filter input;
a data output terminal; and
a clock input terminal; and
a ring counter coupled to the clock input terminals of the registers.

2. The FIR filter of claim 1, further comprising a plurality of convolution operators each coupled to the data output terminal of a respective register.

3. The FIR filter of claim 2, further comprising a first plurality of multiplexers each coupled to a respective convolution operator.

4. The FIR filter of claim 3, wherein the each first multiplexer receives a plurality of convolution coefficients and outputs one of the convolution coefficients to the respective convolution operator.

5. The FIR filter of claim 2, further comprising a second plurality of multiplexers each coupled a respective convolution operator.

6. The FIR filter of claim 5, wherein each second multiplexer receives output signals from a plurality of the registers and outputs one of the output signals to the convolution operator.

7. The FIR filter of claim 2, further comprising a summer coupled to the convolution operators.

8. The FIR filter of claim 7, wherein the summer is configured to sum output signals of the convolution operators.

9. The FIR filter of claim 1, wherein the ring counter includes a plurality of flip-flops coupled in a ring configuration, each flip-flop having an output coupled to a clock input terminal of a respective register and to an input of a next flip-flop in the ring configuration.

10. A finite impulse response filter, comprising:
n registers each including:
a data input terminal;
a data output terminal; and
a clock input terminal; and
a ring counter including n flip-flops coupled in a ring configuration and each coupled to a clock input of a respective register.

11. The FIR filter of claim 10, further comprising a filter input coupled to the data input terminal of each register.

12. The FIR filter of claim 11, wherein the filter input is configured to pass input data values to the data input terminals of each register in accordance with a filter clock signal having a first frequency.

13. The FIR filter of claim 12, wherein each flip-flop outputs a respective register clock signal with a second frequency to the clock input terminal of the corresponding register.

14. The FIR filter of claim 13, wherein the second frequency is approximately equal to the first frequency divided by n.

15. The FIR filter of claim 14, wherein each of the register clock signals are out of phase with each other.

16. The FIR filter of claim 14, wherein only one of the register clock signals is high at each cycle of the filter clock.

17. A method, comprising:
passing data values from a filter input of a finite impulse response (FIR) filter to data input terminals of each of a plurality of registers;
passing a pulse through a ring counter coupled to the registers and including a plurality of flip-flops coupled in a ring configuration; and
controlling clock input terminals of the registers with the ring counter based on the pulse.

18. The method of claim 17, further comprising providing a respective data value from the filter input on each clock cycle of a filter clock signal.

19. The method of claim 18, further comprising processing each data value with only one of the registers.

20. The method of claim 19, further comprising processing each data value with only one of the registers based on the pulse.
